(19) United States
(12) Patent Application Publication
(10) Pub. No.: US 2018/0331061 A1
(43) Pub. Date: Nov. 15, 2018

(54) INTEGRATED DEVICE COMPRISING BUMP ON EXPOSED REDISTRIBUTION INTERCONNECT

(71) Applicant: QUALCOMM Incorporated, San Diego, CA (US)

(72) Inventors: Dongming He, San Diego, CA (US); Lily Zhao, San Diego, CA (US); Wei Wang, San Diego, CA (US); Ahmer Syed, Rancho Santa Fe, CA (US)

(21) Appl. No.: 15/843,865

(22) Filed: Dec. 15, 2017

Related U.S. Application Data
(60) Provisional application No. 62/505,069, filed on May 11, 2017.

(51) Int. Cl. H01L 23/00; H01L 23/31; H01L 23/29; H01L 21/56

(52) U.S. Cl. CPC H01L 24/13; H01L 21/02164; H01L 23/3192; H01L 23/293; H01L 24/11; H01L 21/56; H01L 2224/13024; H01L 2224/0233; H01L 2924/2064; H01L 2224/0231; H01L 2224/02377; H01L 2224/11001; H01L 2924/35121; H01L 2924/3512; H01L 2224/05124; H01L 2224/0239; H01L 23/291; H01L 23/3171

(57) ABSTRACT

A device comprising a semiconductor die and a redistribution portion coupled to the semiconductor die. The redistribution portion includes a passivation layer and a redistribution interconnect comprising a first surface and a second surface opposite to the first surface. The redistribution interconnect is formed over the passivation layer such that the first surface is over the passivation layer and the second surface is free of contact with any passivation layer. The device includes a bump interconnect coupled to the second surface of the redistribution interconnect. In some implementations, the bump interconnect comprises a surface that faces the redistribution interconnect, and wherein an entire surface of the bump interconnect that faces the redistribution interconnect is free of contact with the passivation layer.

### CROSS REFERENCE TO RELATED APPLICATION

This application claims priority to and the benefit of Provisional Application No. 62/505,069 filed on May 11, 2017 in the U.S. Patent and Trademark Office, the entire contents of which is incorporated herein by reference.

### BACKGROUND

### Field

Various features relate to integrated devices, but more specifically to integrated devices that include one or more bumps on an exposed redistribution interconnect.

### Background

FIG. 1 illustrates an integrated device 100 coupled to a printed circuit board (PCB) 180 through a plurality of solder interconnects 106. The integrated device 100 includes a substrate 102, a die 110 and an encapsulation layer 105. The die 110 is coupled to the substrate 102 through a plurality of interconnects 104. The encapsulation layer 105 encapsulates the die 110. The die 110 may include a pad 112, a first passivation layer 143, a second passivation layer 145 and an underbump metallization (UBM) layer 144. The die 110 may include a silicon substrate, an active device layer and metal interconnect layers. The plurality of interconnects 104 may include a bump interconnect 146 and a solder interconnect 148. The UBM layer 144 is coupled to the pad 112. The bump interconnect 146 is coupled to the UBM layer 144. The solder interconnect 148 is coupled to the bump interconnect 146 and a pad 120. The pad 120 is part of the substrate 102.

One of the drawbacks of the configuration of FIG. 1 is that there is a lot of stress that is being applied to the area around the pad 112, which is surrounded by a lot of extremely low K (ELK), ultra low K (ULK) and/or low K dielectric layers (e.g., located in the die 110). These dielectric layers can be very sensitive to peeling stress, and can crack as a result of too much stress being applied during a process of coupling the integrated device 100 to the PCB 180.

FIG. 2 illustrates a profile view of another device 200 (e.g., wafer level package or flip chip device with a redistribution layer). The device 200 includes a substrate 201, several lower metal and lower dielectric layers 202, a pad 204, a first passivation layer 206, a second passivation layer 208, a redistribution layer 210, a third passivation layer 212, and an under bump metallization (UBM) layer 214. The pad 204, the first metal layer 210 and the UBM layer 214 are a conductive material (e.g., copper). FIG. 2 also illustrates a solder interconnect 216 on the package 200. Specifically, the solder interconnect 216 is coupled to the UBM layer 214. The third passivation layer 212 covers the redistribution layer 210. The third passivation layer 212 and the second passivation layer 208 are typically polymer materials with a coefficient of thermal expansion (CTE) that is very different from coefficients of thermal expansion (CTE) for the redistribution layer 210 and the bulk silicon substrate 201. Materials with different coefficients of thermal expansion (CTE) will expand and contract, differently and/or at different rates. The substantial difference in the coefficient of thermal expansion (CTE) of the passivation layer(s) (e.g., 212, 208), and the redistribution layer 210/the substrate 201 can lead to warpage issues for the device 200, as the passivation layer(s) (e.g., 212, 208), and the redistribution layer 210/the substrate 201, expand and contract differently, and/or at different rates. Warpages issues for the device 200 can lead to cracks, further damaging the device 200 or lead to joint open/short after the device 200 is mounted on a PCB (e.g., 180). The thicker the passivation layer(s) (e.g., 208, 212), the higher the warpage. The larger the device 200 size, the higher the warpage.

Therefore, there is a need for a device (e.g., integrated device) with improved crack resistance and/or less warpages, while at the same time meeting the needs and/or requirements of devices (e.g., mobile computing devices and/or wearable computing devices).

### SUMMARY

Various features relate to integrated devices, but more specifically to integrated devices that include one or more bumps on an exposed redistribution interconnect.

One example provides a device that includes a semiconductor die, a redistribution portion coupled to the semiconductor die, and a bump interconnect. The redistribution portion includes a passivation layer and a redistribution interconnect comprising a first surface and a second surface opposite to the first surface. The redistribution interconnect is formed over the passivation layer such that the first surface is over the passivation layer and the second surface is free of contact with any passivation layer. The bump interconnect is coupled to the second surface of the redistribution interconnect.

Another example provides an apparatus that includes a semiconductor die, a redistribution portion coupled to the semiconductor die, and a bump interconnect. The redistribution portion includes means for passivation and means for interconnect redistribution comprising a first surface and a second surface opposite to the first surface. The means for interconnect redistribution is formed over the means for passivation such that the first surface is over the means for passivation and the second surface is free of contact with any means for passivation. The bump interconnect is coupled to the second surface of the means for interconnect redistribution.

Another example provides a method for fabricating a device. The method provides a semiconductor die. The method forms a redistribution portion over the semiconductor die, where forming the redistribution portion includes forming a passivation layer; and forming a redistribution interconnect comprising a first surface and a second surface opposite to the first surface, the redistribution interconnect formed over the passivation layer such that the first surface is over the passivation layer and the second surface is free of contact with any passivation layer. The method couples a bump interconnect to the second surface of the redistribution interconnect.

### BRIEF DESCRIPTION OF THE DRAWINGS

Various features, nature and advantages may become apparent from the detailed description set forth below when taken in conjunction with the drawings in which like reference characters identify correspondingly throughout.

FIG. 1 illustrates a profile view of an integrated device coupled to a printed circuit board (PCB).

FIG. 2 illustrates a profile view of an integrated device that includes a redistribution layer.

FIG. 3 illustrates a profile view of an integrated device that includes a bump interconnect coupled to a redistribution interconnect.

FIG. 4 illustrates a plan view of a redistribution interconnect in an integrated device.

FIG. 5 illustrates a plan view of a layout for bump interconnects in an integrated device.

FIG. 6 illustrates a profile view of an integrated device that includes a bump interconnect coupled to a redistribution interconnect, where the redistribution interconnect and bump side wall are covered with a coating.

FIG. 7 (comprising FIGS. 7A-7C) illustrates an exemplary sequence for fabricating an integrated device that includes a bump interconnect coupled to a redistribution interconnect.

FIG. 8 illustrates an exemplary flow diagram of a method for fabricating an integrated device that includes a bump interconnect coupled to a redistribution interconnect.

FIG. 9 illustrates a profile view of a package that includes an integrated device comprising a bump interconnect coupled to a redistribution interconnect.

FIG. 10 illustrates various electronic devices that may integrate a die, an integrated device, a device package, a package, an integrated circuit and/or PCB described herein.

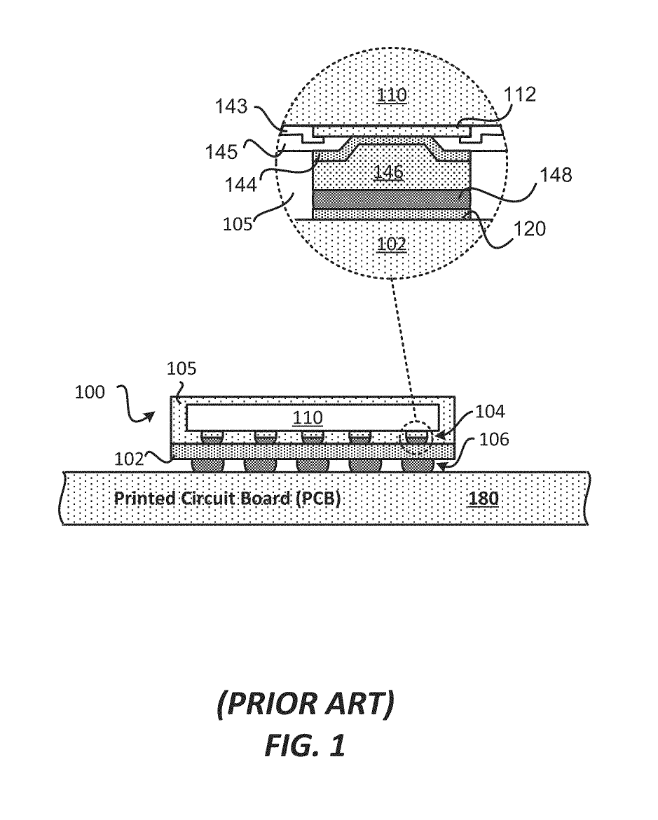

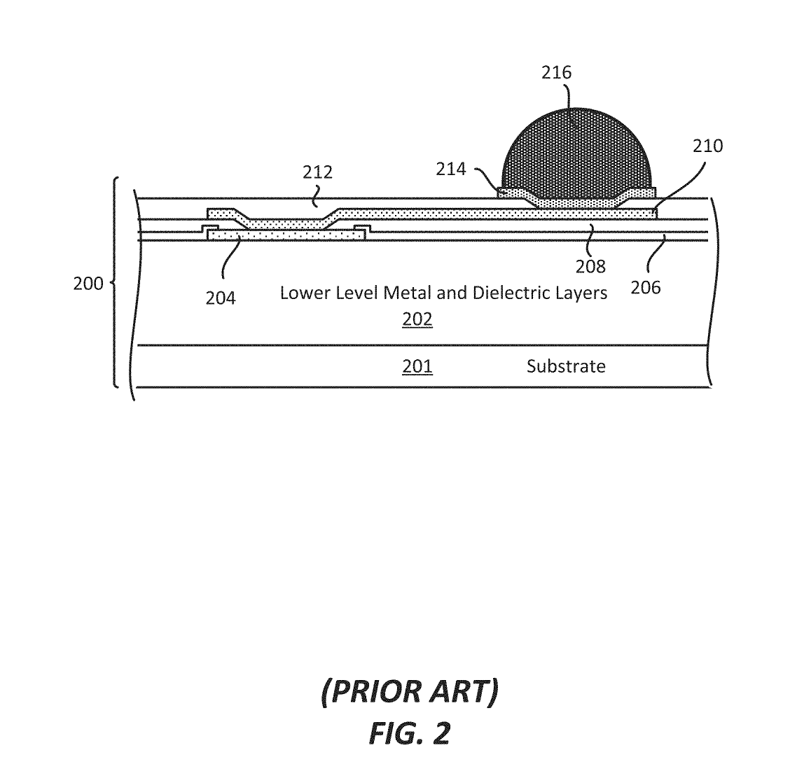

### DETAILED DESCRIPTION

In the following description, specific details are given to provide a thorough understanding of the various aspects of the disclosure. However, it will be understood by one of ordinary skill in the art that the aspects may be practiced without these specific details. For example, circuits may be shown in block diagrams in order to avoid obscuring the aspects in unnecessary detail. In other instances, well-known circuits, structures and techniques may not be shown in detail in order not to obscure the aspects of the disclosure.

The present disclosure describes a device that includes a semiconductor die, a redistribution portion coupled to the semiconductor die, and a bump interconnect. The redistribution portion includes a passivation layer and a redistribution interconnect comprising a first surface and a second surface opposite to the first surface. The redistribution interconnect is formed over the passivation layer such that the first surface is over the passivation layer and the second surface is free of contact with any passivation layer. The bump interconnect is coupled to the second surface of the redistribution interconnect. In some implementations, the bump interconnect includes a surface that faces the redistribution interconnect, and an entire surface of the bump interconnect that faces the redistribution interconnect touches the redistribution interconnect. In some implementations, the bump interconnect comprises a surface that faces the redistribution interconnect, and where an entire surface of the bump interconnect that faces the redistribution interconnect is free of contact with the passivation layer.

### Exemplary Integrated Device Comprising a Bump Interconnect Coupled to a Redistribution Interconnect

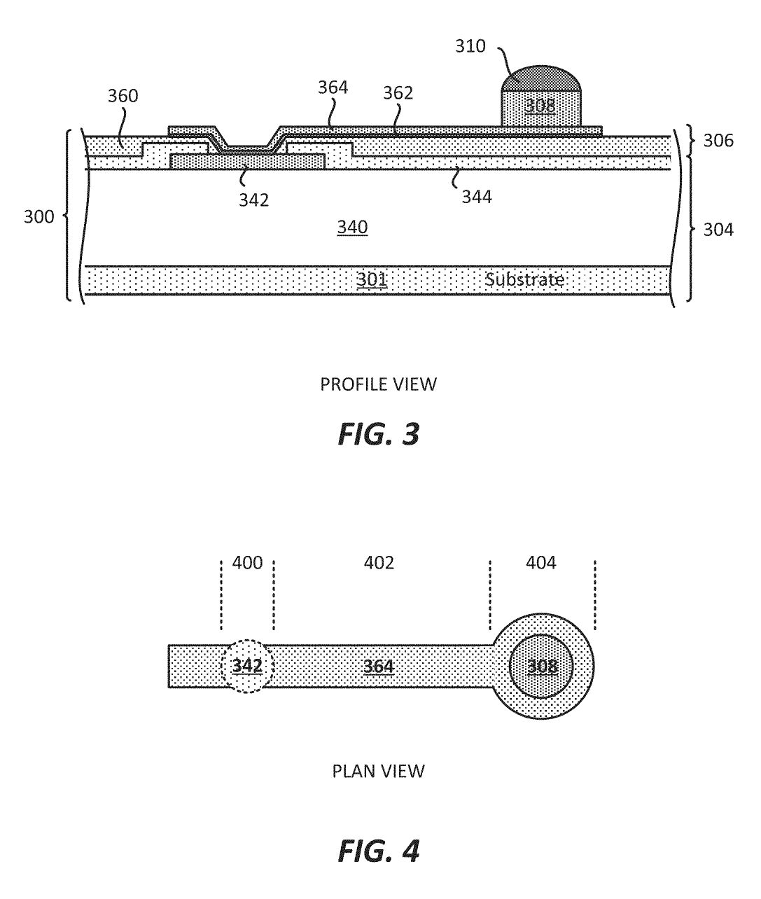

FIG. 3 illustrates a profile view of a device 300 (e.g., integrated device) that includes at least one bump interconnect coupled to a redistribution interconnect. The redistribution interconnect may include a first surface and a second surface, where the second surface of the redistribution interconnect is exposed and/or free of contact with a passivation layer. The second surface of the redistribution interconnect may be opposite to the first surface of the redistribution interconnect.

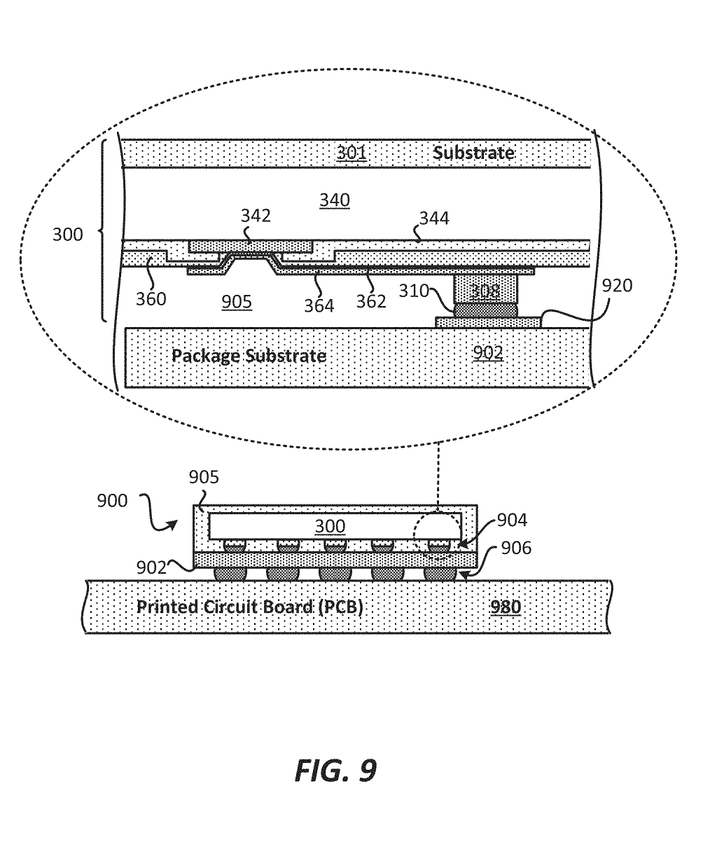

The device 300 includes a die 304 (e.g., semiconductor die), a redistribution portion 306, and at least one bump interconnect 308. The die 304 may include a substrate 301 (e.g., silicon substrate) and at least one dielectric layer 340 (e.g., lower level dielectric layer). In some implementations, the at least one dielectric layer 340 may be formed over the substrate 301. In some implementations, the die 304 may form a bare die of the device 300. In some implementations, the redistribution portion 306 and/or the at least one bump interconnect 308 may be considered part of the die 304. In some implementations, the device 300 is coupled to a package substrate and an encapsulation layer that at least partially encapsulates the device 300. The device 300 may be coupled to the package substrate through a plurality of interconnects (e.g., solder interconnects). An example of how the device 300 may be formed in a package (e.g., integrated package) is further described below in FIG. 9.

The die 304 includes the substrate 301, at least one dielectric layer 340 (e.g., lower level dielectric layers), at least one pad 342, a first passivation layer 344 and a second passivation layer 360. The at least one pad 342 and the first passivation layer 344 is over the at least one dielectric layer 340. In some implementations, the first passivation layer 344 includes a hard passivation. In some implementations, the second passivation layer 360 includes a polymer passivation. The first passivation layer 344 and/or the second passivation layer 360 may be means for passivation.

The die 304 may also include several metal layers (e.g., lower level metal layers) that are located in or over the at least one dielectric layer 340. These metal layers (e.g., M1 metal layer, M2 metal layer, M3 metal layer, M4 metal layer, M5 metal layer, M6 metal layer, M7 metal layer), which are not shown, in and/or over the at least one dielectric layer 340 may define interconnects (e.g., traces, vias, pads) in the die 304 of the device 300. The above metal layer(s) (M1, M2, etc . . . ) may be formed over the substrate 301. In some implementations, the at least one pad 342 may be over a top level metal layer of the die 304 of the device 300. The at least one pad 342 may be coupled (e.g., directly coupled) to a metal layer (e.g., M7 metal layer) of the die 304 of the device 300. The at least one pad 342 may include aluminum. In some implementations, the die 304 of the device 300 may include a substrate (e.g., silicon) and several transistors and/or other electronic components. The transistors may be part of the active device layer that is formed over the substrate of the die 304.

The redistribution portion 306 is coupled to the die 304. The redistribution portion 306 includes the second passivation layer 360, a seed layer 362, a redistribution interconnect 364. In some implementations, the second passivation layer 360 is a soft passivation. In some implementations, the second passivation layer 360 may include one or more of a polyimide layer (PI), a Polybenzoxazole (PBO) and/or other polymer layers. In some implementations, a polymer may absorb moisture. The second passivation layer 360 is located over the first passivation layer 344. In some implementations, the first passivation layer 344 may be considered part of the redistribution portion 306. In some implementations, the first passivation layer 344 is a hard passivation that protects against moisture. Examples of the first passivation layer 344 include silicon nitride and/or silicon oxide. In some implementations, the silicon nitride is hermetic against moisture and/or corrosion. In some implementations, silicon nitride and silicon oxide form one or more layers that has a high hardness and modulus. In some implementations, the silicon nitride and/or silicon oxide may be formed using a plasma enhanced chemical vapor deposition (PECVD) process.

The seed layer 362 is coupled to the pad 342. The redistribution interconnect 364 is formed over the seed layer 362. The redistribution interconnect 364 may include an adhesion layer. In some implementations, the redistribution interconnect 364 includes the seed layer 362. Thus, in some implementations, the seed layer 362 may be considered part of the redistribution interconnect 364. The redistribution interconnect 364 may be considered to be coupled to the pad 342. In some implementations, the seed layer 362 is optional. The redistribution interconnect 364 is formed over the second passivation layer 360 such that a surface (e.g., second surface, surface facing towards the bump interconnect 308) of the redistribution interconnect 364 is exposed and/or free of contract with any passivation layer. In some implementations, a surface of the redistribution interconnect 364 is not covered by any passivation layer. However, it is noted the surface (e.g., second surface, surface facing towards the bump interconnect 308) of the redistribution interconnect 364 may nonetheless be covered with other materials that are not considered a passivation layer. The second surface of the redistribution interconnect 364 may be opposite to a first surface of the redistribution interconnect 364. In some implementations, the first surface of the redistribution interconnect 364 may be a surface comprising the seed layer 362, and the second surface of the redistribution interconnect 364 is a surface coupled to the bump interconnect 308 and/or facing the bump interconnect 308. The redistribution interconnect 364 may be a means for interconnect redistribution. In some implementations, the redistribution interconnect 364 may include a thickness that is in a range of about 2-10 micrometers (μm).

In some implementations, the bump interconnect 308 includes a surface that faces the redistribution interconnect 364, and the entire surface of the bump interconnect 308 that faces the redistribution interconnect touches the redistribution interconnect 364. This implementation helps produce a stronger and more reliable joint (because of more surface area coupling) between the bump interconnect 308 and the redistribution interconnect 364, and the second passivation layer 360 under the redistribution interconnect 364, which in turns produces one or more more reliable paths for electrical signals in the device 300. The bump interconnect 308 may include copper.

There are other technical advantages to the configuration of FIG. 3. First, by offsetting the location of the bump interconnect 308 so that it is not directly over the pad 342, there is less likelihood of cracking to occur, especially around the area of the pad 342. In some implementations, the configuration of the device 300 can result in some instances, up to 77 percent less stress around the pad 342, than other devices (e.g., device 100). Second, by keeping a surface (e.g., top surface, surface facing the bump interconnect) of the redistribution interconnect 364 exposed and/or free of any passivation layer, warpages issues are less likely to occur, thereby producing a device 300 that is less likely to fail. Third, the overall cost of device 300 is reduced by not having to form additional passivation layers over the redistribution interconnect 364.

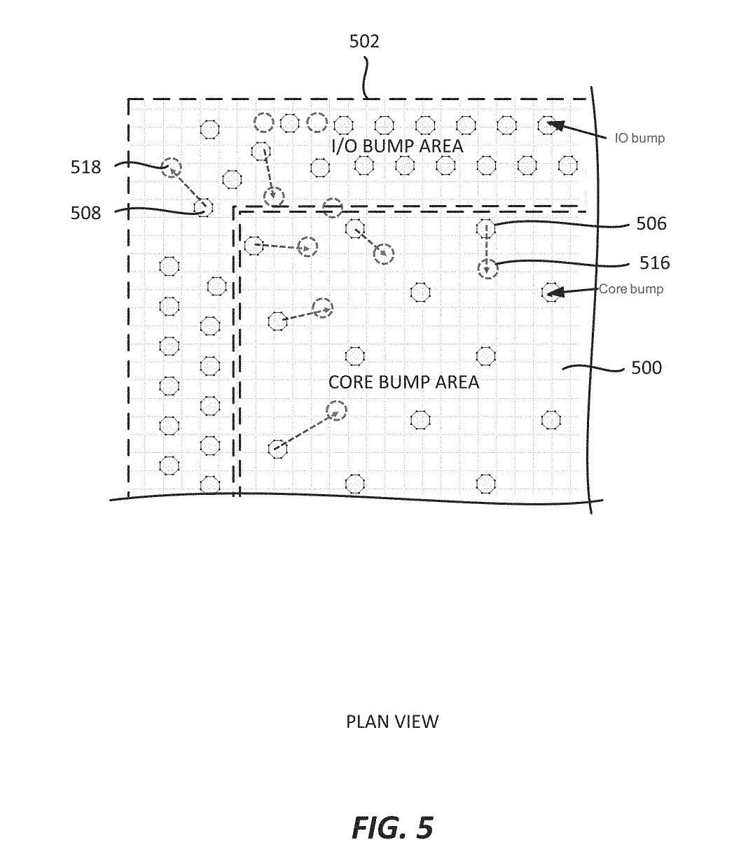

As will be further described in FIG. 5, in some implementations, the redistribution portion 306 allows signals from input/output (I/O) pads and/or core pads of the die to be available (e.g., fan out) in other locations of the device 300. In some implementations, the redistribution interconnect 364 redistribute signaling from the I/O pads (e.g., pad 342) or core pads of the die to other locations in the device 300.

In some implementations, the redistribution interconnect 364 is coupled (e.g., directly coupled) to the at least one pad 342. The redistribution interconnect 364 may include the seed layer 362. In some implementations, the seed layer 362 is coupled (e.g., directly coupled) to the at least one pad 342. The seed layer 362 may include metal (e.g., copper). A redistribution interconnect is a metal layer of a redistribution portion of a device. A redistribution layer may include one or more redistribution interconnects, which are formed on the same metal layer of the redistribution portion. A redistribution portion of an integrated device may include several redistribution layers, each redistribution layer may include one or more redistribution interconnects. Thus, for example, a redistribution portion may include a first redistribution interconnect on a first redistribution metal layer, and a second redistribution interconnect on a second redistribution metal layer that is different than the first redistribution metal layer.

FIG. 4 illustrates a plan view of a redistribution interconnect of a redistribution portion of a device. As shown in FIG. 4, the redistribution interconnect 364 includes a first redistribution interconnect portion 400, a second redistribution interconnect portion 402, and a third redistribution interconnect portion 404. The first redistribution interconnect portion 400 is coupled to the pad 342. The first redistribution interconnect portion 400 is coupled to the second redistribution interconnect portion 402. The second redistribution interconnect portion 402 may be a redistribution trace. The second redistribution interconnect portion 402 is coupled to the third redistribution interconnect portion 404. The third redistribution interconnect portion 404 may be a redistribution pad. The third redistribution interconnect portion 404 is coupled to the bump interconnect 308. The bump interconnect 308 includes a first surface (e.g., bottom surface), a second surface (e.g., top surface) and a third surface (e.g., side surface). In some implementations, the entire first surface of the bump interconnect 308 is coupled to the third redistribution interconnect portion 404. In some implementations, the first surface of the bump interconnect 308 includes all surface that faces the redistribution interconnect 364. It is noted that different implementations may use different shapes, designs, and/or sizes for the third redistribution interconnect portion 404.

An interconnect is an element or component of a device (e.g., integrated device, package, integrated circuit (IC) device, die) and/or a base (e.g., device package base, package substrate, printed circuit board (PCB), interposer) that allows or facilitates an electrical connection between two points, elements and/or components. In some implementations, an interconnect may include a trace, a via, a pad, a pillar, a redistribution metal layer, and/or an under bump metallization (UBM) layer. In some implementations, an interconnect includes an electrically conductive material that provides an electrical path for a signal (e.g., data signal, ground signal, power signal). An interconnect may include more than one interconnect.

As mentioned above, in some implementations, the redistribution portion 306 allows signals from input/output (I/O) pads and/or core pads of the die to be available (e.g., fan out) in other locations of the device 300. In some implementations, the redistribution interconnect 364 redistribute signaling from the I/O pads (e.g., pad 342) or core pads of the die to other locations in the device 300.

FIG. 5 illustrates a plan view of part of a cross section of the device 300. In some implementations, the plan view is a cross section between the device 300 and a package substrate. The device 300 includes a core bump area 500 and an input/output (I/O) bump area 502. The core bump area 500 is an area of the device 300 where core bump interconnects couple to redistribution interconnects. The core bump area 500 may be used for bump interconnects that provide one or more electrical paths for power and/or ground. The I/O bump area 502 is an area of the device 300 where I/O bump interconnects couple to redistribution interconnects. The I/O bump area 502 may be used for bump interconnects that provide one or more electrical paths for input signals and/or output signals.

As shown in FIG. 5, the bump interconnect located at location 506 of the core bump area 500 may be moved to location 516. The bump interconnect located at location 508 of the I/O bump area 502 may be moved to the location 518. Different implementations may move the location of the bump interconnects differently.

In some implementations, a redistribution interconnect (e.g., 364) may be covered by a material that is not a passivation layer.

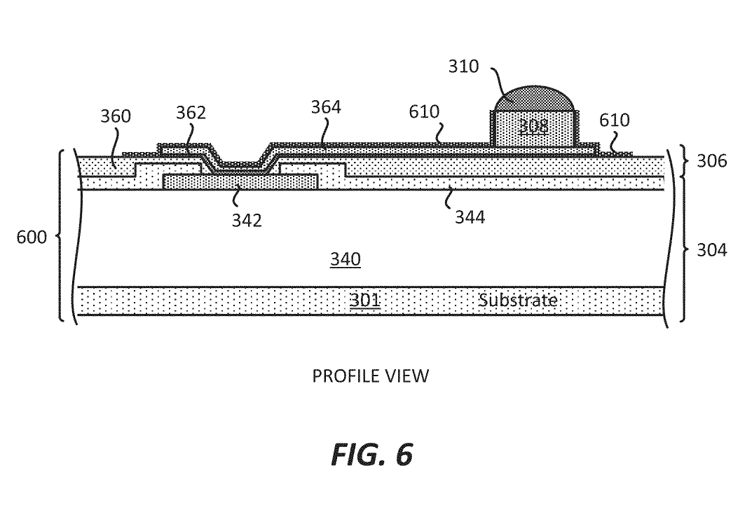

FIG. 6 illustrates a profile view of a device 600 (e.g., integrated device) that includes at least bump interconnect coupled to a redistribution interconnect. The device 600 is similar to the device 300 of FIG. 3. The device 600 may includes all of the components and materials, as described in the device 300. The device 600 may include a redistribution interconnect that includes a first surface and a second surface, where the second surface of the redistribution interconnect is exposed and/or free of contact with a passivation layer. The second surface of the redistribution interconnect may be opposite to the first surface of the redistribution interconnect. The device 600 may include a second surface of the redistribution interconnect that is covered with a coating. The coating may be different than a passivation layer. In some implementations, the redistribution interconnect 364 may be covered by a material that is not a passivation layer. The device 600 may include a bump interconnect where a side surface is covered with a coating. The coating may help protect the bump interconnect and/or the redistribution interconnect. A first surface of the redistribution interconnect may include the seed layer 362 (e.g., copper).

As shown in FIG. 6, the device 600 includes a coating 610 that is formed over the redistribution interconnect 364 (e.g., second surface of the redistribution interconnect 364). In some implementations, the coating 610 is formed over any surface of the redistribution interconnects that is exposed, not covered by a passivation layer and/or not covered by a bump interconnect. The coating 610 may include a metal layer, such as nickel. Different implementations may use different thicknesses for the coating 610. In some implementations, the coating 610 includes a thickness of about 1 micrometer (μm).

FIG. 6 also illustrates that the coating 610 is formed on the bump interconnect 308. More specifically, the coating 610 is formed on a side surface of the bump interconnect 308. It is also noted that in some implementations, the coating 610 may be formed over portions of the second passivation layer 360.

Having described various devices that include a bump interconnect coupled to a redistribution interconnect, an exemplary sequence for fabricating such a device will now be described below.

### Exemplary Sequence for Fabricating an Integrated Device That Includes a Bump Interconnect coupled to a Redistribution Interconnect

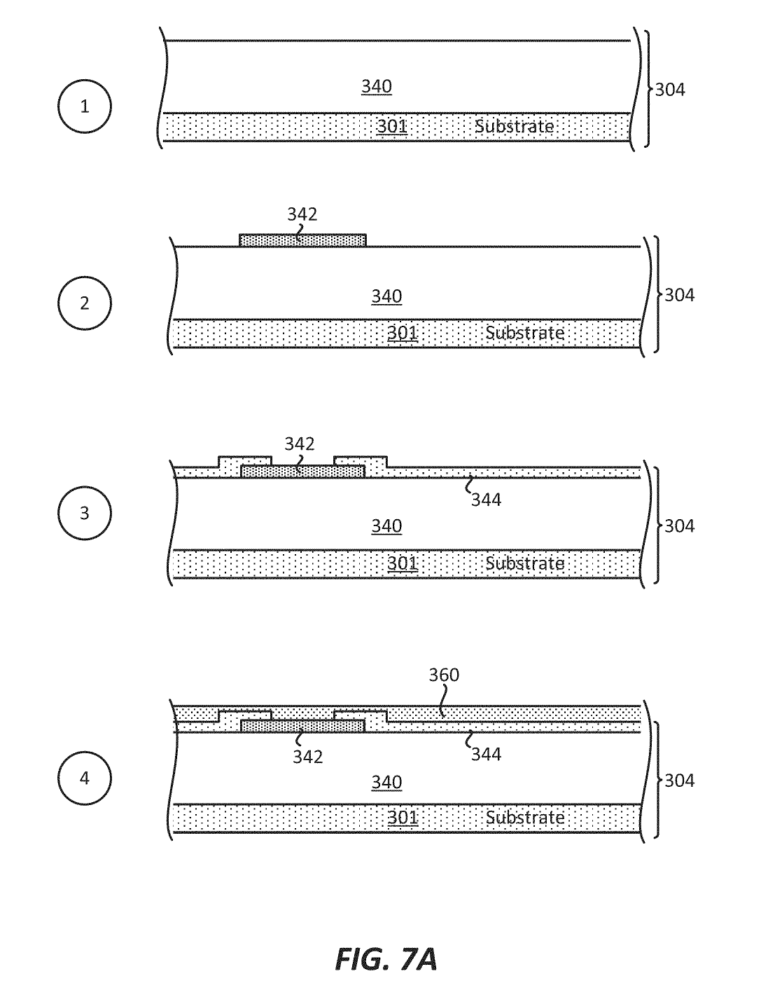

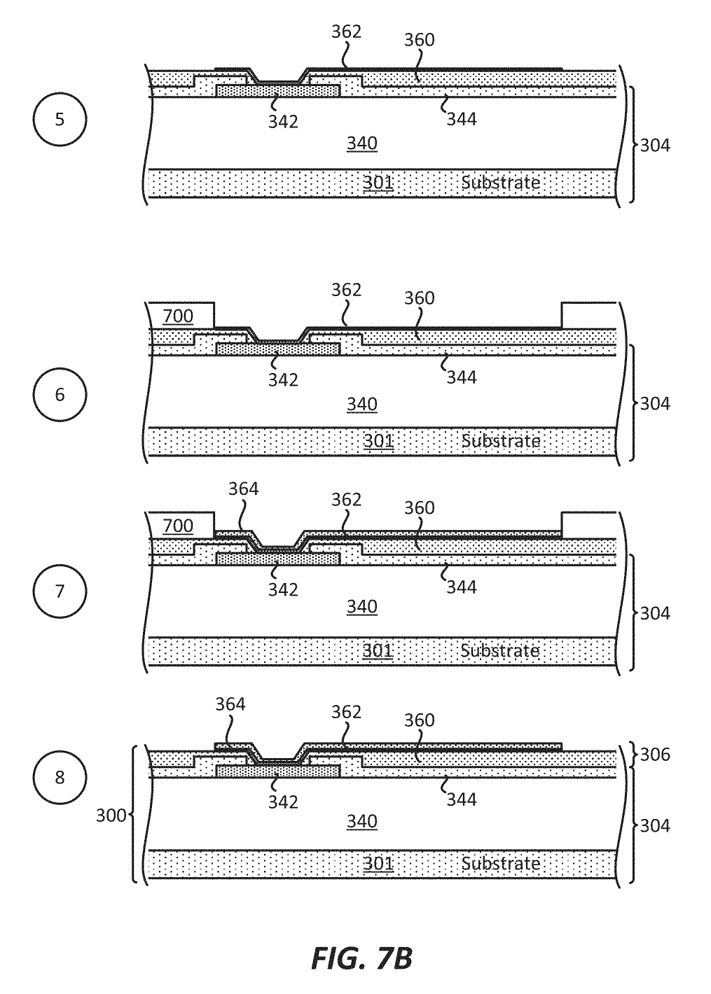

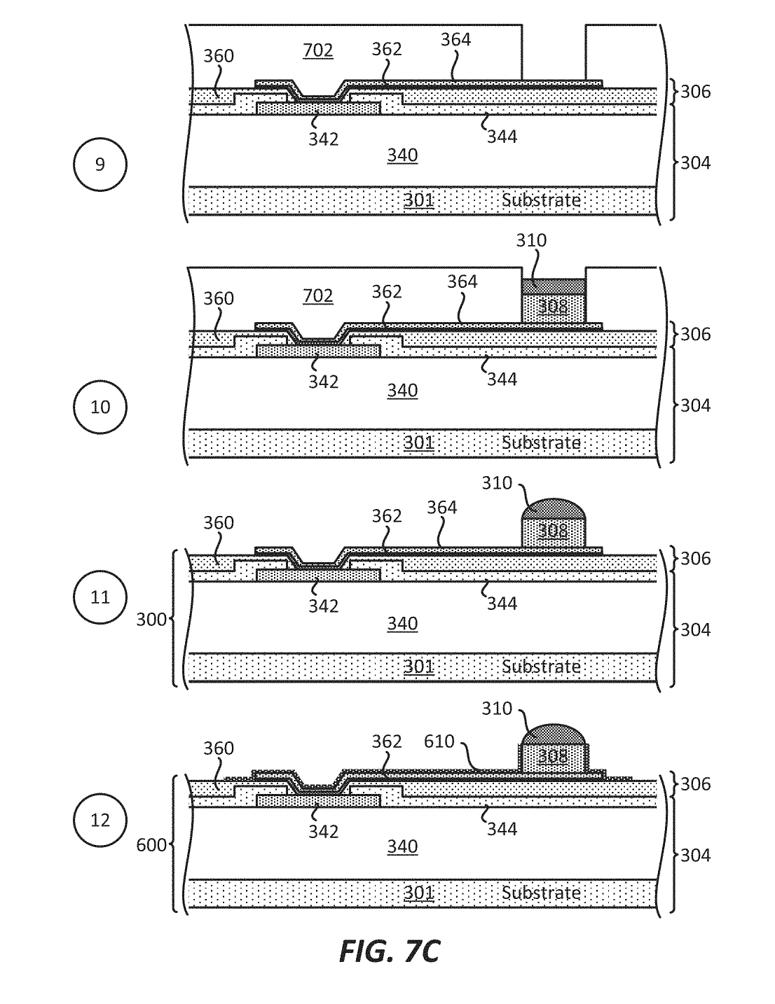

In some implementations, fabricating a device that includes at least one bump interconnect coupled to a redistribution interconnect includes several processes. FIG. 7 (which includes FIGS. 7A-7C) illustrates an exemplary sequence for providing or fabricating a device (e.g., integrated device) that includes at least one bump interconnect coupled to a redistribution interconnect. In some implementations, the sequence of FIGS. 7A-7C may be used to provide or fabricate the devices of FIGS. 3, 6 and/or other devices described in the present disclosure.

It should be noted that the sequence of FIGS. 7A-7C may combine one or more stages in order to simplify and/or clarify the sequence for providing or fabricating a device that includes at least one bump interconnect coupled to a redistribution interconnect. In some implementations, the order of the processes may be changed or modified. In some implementations, one or more of processes may be replaced or substituted without departing from the spirit of the disclosure.

Stage 1 of FIG. 7A illustrates a state after a die 304 is provided. The die 304 may include a substrate 301 (e.g., silicon substrate) and/or at least one dielectric layer 340. The die 304 may also include a device layer (e.g., active device layer) over the substrate 301. The device layer may include transistors and/or other electronic components. The substrate 301 may be a wafer. The at least one dielectric layer 340 may include several lower level metal layers (e.g., M1 metal layer, M2 metal layer, M3 metal layer, M4 metal layer, M5 metal layer, M6 metal layer, M7 metal layer). For purpose of clarity, these lower level metal layers are not shown. The lower level metal layers may define at least one lower level interconnect (e.g., die interconnects). These lower level interconnects may include traces, vias and/or pads. The lower level metal layers and the at least one lower level dielectric layers may be part of an inner portion of the die, as mentioned in FIG. 3. Different processes may be used to form the lower level metals layers. In some implementations, the lower level metal layers and the at least one lower level dielectric layers may be formed over the device layer (e.g., active device layer) of the substrate 301.

Stage 2 illustrates a state after at least one pad (e.g., pad 342) is provided (e.g., formed) over the at least one dielectric layer 340. In some implementations, the pad 342 is coupled to one of the lower level metal layers (not shown). In some implementations, the pad 342 is a top metal layer. In some implementations, the pad 342 is an aluminum pad. However, different implementations may use different materials for the pad 342. Different implementations may use different processes for forming the pad 342 over the at least one dielectric layer 340. For example, in some implementations, lithography, etching and/or plating processes may be used to provide the pad 342 over the at least one dielectric layer 340.

Stage 3 illustrates a state after a passivation layer (e.g., first passivation layer 344) is formed over the at least one dielectric layer 340 (e.g., lower level dielectric layer). Different implementations may use different materials for the passivation layer. The first passivation layer 344 may be a hard passivation layer. As shown in stage 3, the first passivation layer 344 is provided over the at least one dielectric layer 340 such that at least a portion of the pad 342 is exposed. In some implementations, stage 3 illustrates a state after a die (e.g., bare die) is provided or fabricated.

Stage 4 illustrates a state after another passivation layer (e.g., second passivation layer 360) is provided over the first passivation layer 344 and the pad 342. Different implementations may use different materials for the second passivation layer 360. In some implementations, the second passivation layer 360 is a soft passivation layer. For example, the second passivation layer 360 may be a polymer passivation layer (e.g., a polyimide layer (PI), a Polybenzoxazole (PBO)).

Stage 5, as shown in FIG. 7B, illustrates a state after a cavity formed in the second passivation layer 360 and a seed layer 362 is formed over the second passivation layer 360 and the pad 342. A sputter process may be used to form the seed layer (e.g., copper).

Stage 6 illustrates a state after a photo resist (PR) layer 700 is provided over the second passivation layer 360. The photo resist (PR) layer 700 may be selectively removed using a photo etching process.

Stage 7 illustrates a state after a redistribution interconnect 364 is formed. The redistribution interconnect 364 may be formed over the seed layer 362. One or more plating processes may be used to form the redistribution interconnect 363. However, different implementations may use different processes for forming the redistribution interconnect 364. The redistribution interconnect 364 may include an adhesion. In some implementations, the redistribution interconnect 364 may be formed using a sputtering and etching process. In some implementations, the seed layer 362 may be considered part of the redistribution interconnect 364.

Stage 8 illustrates a state after the photo resist (PR) layer 700 has been removed, leaving behind the redistribution interconnect 364. It is noted that sputtering, etching and/or plating processes may be repeated to include more redistribution interconnects.

Stage 9, as shown in FIG. 7C, illustrates a state after a photo resist (PR) layer 702 is provided over the second passivation layer 360 and portions of the redistribution interconnect 364. The photo resist (PR) layer 702 may be selectively removed using a photo etching process.

Stage 10 illustrates a state after a bump interconnect 308 is formed in the cavity of the photo resist (PR) 702. A plating process may be used to form the bump interconnect 308. Stage 10 also illustrate a solder interconnect 310 provided over the bump interconnect 308.

Stage 11 illustrates a state after the photo resist (PR) layer 702 has been removed, leaving behind the bump interconnect 308 and the solder interconnect 310. In some implementations, Stage 11 illustrates the device 300 of FIG. 3.

Stage 12 illustrates a state after a coating 610 has been formed over portions of the redistribution interconnect 364 and/or portions of the bump interconnect 308. The coating 610 may include nickel. The coating 610 may be optional in some implementations. Different implementations may provide the coating 610 differently. In some implementations, Stage 12 illustrates the device 600 of FIG. 6.

It is noted that the sequence of FIG. 7 may be used to fabricate (e.g., concurrently fabricate) several dies and/or devices on a wafer, with each die and/or device comprising several bump interconnects. The wafer is then singulated (e.g., cut) into individual dies and/or devices. These singulated dies, devices and/or packages may then be coupled to a printed circuit board (PCB).

### Exemplary Flow Diagram of a Method for Fabricating an Integrated Device That Includes a Bump Interconnect coupled to a Redistribution Interconnect

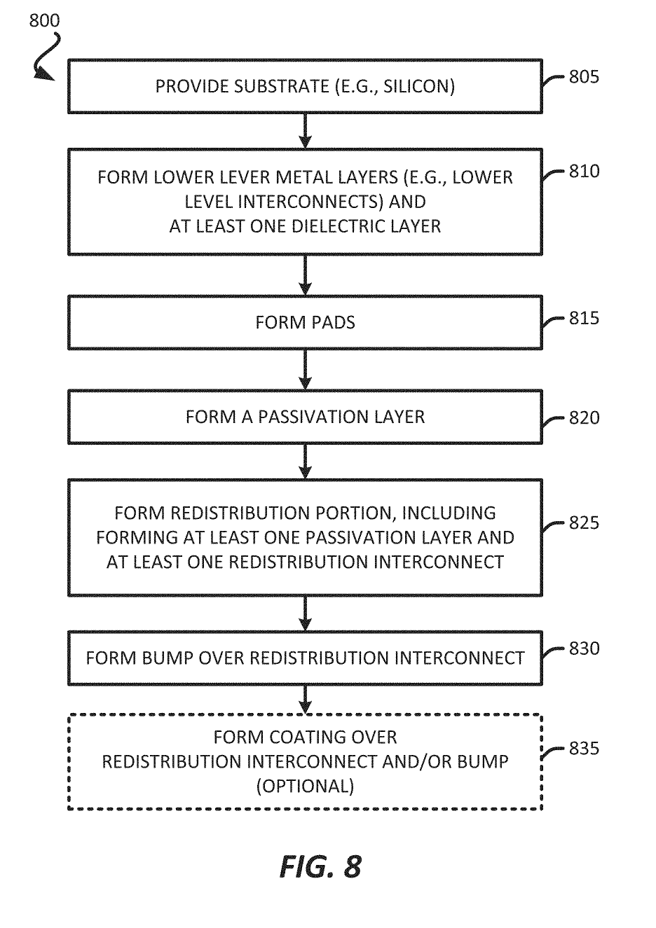

In some implementations, providing a device that includes at least one bump interconnect coupled to the redistribution interconnect includes several processes. FIG. 8 illustrates an exemplary flow diagram of a method 800 for providing or fabricating a device (e.g., integrated device) that includes at least one bump interconnect coupled to the redistribution interconnect. In some implementations, the method 800 of FIG. 8 may be used to provide or fabricate the devices (e.g., 300, 600) of FIGS. 3, 6 and/or other devices described in the present disclosure.

It should be noted that the sequence of FIG. 8 may combine one or more processes in order to simplify and/or clarify the method for providing or fabricating a device that includes at least one bump interconnect coupled to the redistribution interconnect. In some implementations, the order of the processes may be changed or modified.

The method provides (at 805) a substrate (e.g., 301). Different implementations may use different materials for the substrate (e.g., silicon substrate, glass substrate, ceramic substrate). The substrate may be the substrate (e.g., 301) of the device 300 or the device 600. The substrate may be part of a wafer. In some implementations, providing the substrate may also include fabricating a device layer (e.g., active device layer) over the substrate. The device layer may include one or more transistors.

The method forms (at 810) several lower level metal layers and at least one lower level dielectric layer over the substrate. Different implementations may form different number of lower level metal layers and lower level dielectric layers (e.g., M1 metal layer, M2 metal layer, M3 metal layer, M4 metal layer, M5 metal layer, M6 metal layer, M7 metal layer). The at least one dielectric layer may be the at least one dielectric layer 340. The lower level metal layers may define at least one lower level interconnect (e.g., die interconnects). These lower level interconnects may include traces, vias and/or pads. The lower level metal layers and the at least one lower level dielectric layer may be part of an inner portion of a die, as mentioned in FIG. 3. Different processes may be used to form the lower level metals layers. In some implementations, the lower level metal layers and at least one lower level dielectric layer may be fabricated over the device layer (e.g., active device layer) of the substrate.

The method forms (at 815) at least one pad over the lower level metal layers and the at least one dielectric layer. In some implementations, the pad is formed such that the pad is coupled to one of the lower level metal layers. In some implementations, the pad is a top metal layer. In some implementations, the pad is an aluminum pad. However, different implementations may use different materials for the pad. Different implementations may use different processes for forming the pad. The pad may be the pad 342.

The method forms (at 820) at least one passivation layer over the lower level metal layer and the at least one dielectric layer. Different implementations may use different materials for the passivation layer. The passivation layer(s) may include the first passivation layer 344 and/or the second passivation layer 360. In some implementations, forming the lower level metal layers, at least one dielectric layer, at least one pad, and/or at least passivation layer forms an inner portion for a die (e.g., die 304). In some implementations, providing the substrate, forming the metal layers and dielectric layers, forming the pads, and forming the passivation layer provides and forms a die (e.g., bare die).

The method forms (at 825) a redistribution portion (e.g., 306) for a package. In some implementations, forming (at 825) the redistribution portion includes forming at least one passivation layer, and at least one redistribution interconnect. Stages 4-8 of FIGS. 7A-7C illustrate an example of forming a redistribution portion, including forming at least one passivation layer, and at least one redistribution interconnect. The redistribution portion may include the redistribution interconnect 364 and/or the seed layer 362.

The method forms (at 830) at least one bump interconnects over the redistribution interconnect of the redistribution portion. The bump interconnect (e.g., 308) is coupled or formed over the redistribution interconnect such that a substantial portion of the surface (e.g., majority of surface, all the surface) of the bump interconnect facing the redistribution interconnect is coupled to the redistribution interconnect. In some implementations, forming at least one bump interconnect includes coupling a solder interconnect to the bump interconnect. A screen printing process may be used to form the solder interconnect over the bump interconnect. Different implementations may form the solder interconnect differently. The solder interconnect may be the solder interconnect 310. The bump interconnect (e.g., 308) that is formed over the redistribution interconnect (e.g., 364) is left exposed and/or free of being covered by a passivation layer on one surface or side of the redistribution interconnect (e.g., 364).

The method optionally forms (at 835) a coating over the redistribution interconnect and/or the bump interconnect. The coating (e.g., 610) may include a metal layer, such as nickel. The coating may be formed over the redistribution interconnect (e.g., 364) and/or a side surface of the bump interconnect (e.g., 308).

It is noted that the method of FIG. 8 may be used to fabricate (e.g., concurrently fabricate) several dies and/or devices on a wafer, with each die and/or device comprising several bump interconnects. The wafer is then singulated (e.g., cut) into individual dies and/or devices. These singulated dies, devices and/or packages may then be coupled to a printed circuit board (PCB).

### Exemplary Package That Includes an Integrated Device Comprising a Bump Interconnect Coupled to a Redistribution Interconnect

FIG. 9 illustrates a device 900 (e.g., package, integrated package) coupled to a printed circuit board (PCB) 980 through a plurality of solder interconnects 906. The device 900 includes a substrate 902, the device 300 and an encapsulation layer 905. The device 300 is coupled to the substrate 902 through a plurality of interconnects 904. The encapsulation layer 905 encapsulates the device 300. The encapsulation layer 905 may include a mold, a resin and/or an epoxy. For example, the encapsulation layer 905 may comprise a composite material that includes epoxy resins, phenolic hardeners, silicas, catalysts, pigments, and/or mold release agents. An encapsulation layer is different than a passivation layer. The device 300 may include a silicon substrate, an active device layer and metal interconnect layers. Although not shown, an underfill may be located between the device 900 and the PCB 980. More specifically, an underfill may be located between the substrate 902 (e.g., package substrate) and the PCB 980. The underfill may at least partially encapsulate the plurality of solder interconnects 906. An underfill may include a composite material that comprises epoxy resin, silica filler, and/or catalysts.

FIG. 9 illustrates that the device 300 includes at least one bump interconnect coupled to a redistribution interconnect. The redistribution interconnect may include a first surface and a second surface, where the second surface of the redistribution interconnect is exposed and/or free of contact with a passivation layer. The second surface of the redistribution interconnect may be opposite to the first surface of the redistribution interconnect. It is noted that an encapsulation layer (e.g., 905) is not the same as a passivation layer (e.g., 344, 360). For example, an encapsulation layer may be a composite material, while a passivation layer may not be a composite material. Moreover, in some implementations, another difference between an encapsulation layer and a passivation layer is that an encapsulation layer typically has a thickness that is in the range of hundreds of micrometers to millimeters, while a passivation layer has a thickness that is in the range of sub-micrometer and micrometers.

The plurality of interconnects 904 may include a bump interconnect 308 and a solder interconnect 310. The bump interconnect 308 is coupled to the redistribution interconnect 364 and/or the seed layer 362. In some implementations, the seed layer 362 may be considered part of the redistribution interconnect 364. Thus, in some implementations, the redistribution interconnect 364 may include the seed layer 362. The bump interconnect 308 is also coupled to the solder interconnect 310. The solder interconnect 310 is coupled to a pad 920 of the substrate 902. In some implementations, the device 900 may include the device 600 instead of the device 300.

### Exemplary Electronic Devices

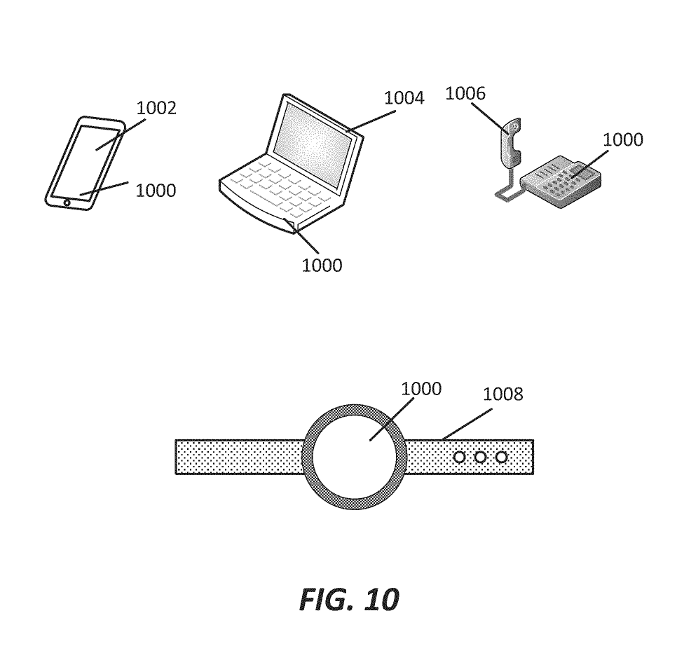

FIG. 10 illustrates various electronic devices that may be integrated with any of the aforementioned device, integrated device, semiconductor device, integrated circuit, die, interposer, package or package-on-package (PoP). For example, a mobile phone device 1002, a laptop computer device 1004, a fixed location terminal device 1006, or a wearable device 1008 may include a device 1000 as described herein. The device 1000 may be, for example, any of the devices described herein. The devices 1002, 1004, 1006 and 1008 illustrated in FIG. 10 are merely exemplary. Other electronic devices may also feature the device 1000 including, but not limited to, a group of devices (e.g., electronic devices) that includes mobile devices, hand-held personal communication systems (PCS) units, portable data units such as personal digital assistants, global positioning system (GPS) enabled devices, navigation devices, set top boxes, music players, video players, entertainment units, fixed location data units such as meter reading equipment, communications devices, smartphones, tablet computers, computers, wearable devices (e.g., watches, glasses), Internet of things (IoT) devices, servers, routers, electronic devices implemented in automotive vehicles (e.g., autonomous vehicles), or any other device that stores or retrieves data or computer instructions, or any combination thereof.

One or more of the components, processes, features, and/or functions illustrated in FIGS. 3-6, 7A-7C and/or 8-10 may be rearranged and/or combined into a single component, process, feature or function or embodied in several components, processes, or functions. Additional elements, components, processes, and/or functions may also be added without departing from the disclosure. It should also be noted FIGS. 3-6, 7A-7C and/or 8-10 and its corresponding description in the present disclosure is not limited to dies and/or ICs. In some implementations, FIGS. 3-6, 7A-7C and/or 8-10 and its corresponding description may be used to manufacture, create, provide, and/or produce devices and/or integrated devices. In some implementations, a device may include a die, an integrated device, a die package, an integrated circuit (IC) device, a device package, an integrated circuit (IC) package, a wafer, a semiconductor device, a package-on-package (PoP) device, and/or an interposer.

The word “exemplary” is used herein to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect coupling between two objects. For example, if object A physically touches object B, and object B touches object C, then objects A and C may still be considered coupled to one another—even if they do not directly physically touch each other. It is further noted that the term “over” as used in the present application in the context of one component located over another component, may be used to mean a component that is on another component and/or in another component (e.g., on a surface of a component or embedded in a component). Thus, for example, a first component that is over the second component may mean that (1) the first component is over the second component, but not directly touching the second component, (2) the first component is on (e.g., on a surface of) the second component, and/or (3) the first component is in (e.g., embedded in) the second component.

Also, it is noted that various disclosures contained herein may be described as a process that is depicted as a flowchart, a flow diagram, a structure diagram, or a block diagram. Although a flowchart may describe the operations as a sequential process, many of the operations can be performed in parallel or concurrently. In addition, the order of the operations may be re-arranged. A process is terminated when its operations are completed.

The various features of the disclosure described herein can be implemented in different systems without departing from the disclosure. It should be noted that the foregoing aspects of the disclosure are merely examples and are not to be construed as limiting the disclosure. The description of the aspects of the present disclosure is intended to be illustrative, and not to limit the scope of the claims. As such, the present teachings can be readily applied to other types of apparatuses and many alternatives, modifications, and variations will be apparent to those skilled in the art.

What is claimed is:

1. A device comprising:
a semiconductor die;
a redistribution portion coupled to the semiconductor die, the redistribution portion comprising:
a passivation layer; and
a redistribution interconnect comprising a first surface and a second surface opposite to the first surface, the redistribution interconnect formed over the passivation layer such that the first surface is over the passivation layer and the second surface is free of contact with any passivation layer; and
a bump interconnect coupled to the second surface of the redistribution interconnect.

2. The device of claim 1, wherein the bump interconnect comprises a surface that faces the redistribution interconnect, and wherein an entire surface of the bump interconnect that faces the redistribution interconnect touches the redistribution interconnect.

3. The device of claim 1, wherein the bump interconnect comprises a surface that faces the redistribution interconnect, and wherein an entire surface of the bump interconnect that faces the redistribution interconnect is free of contact with the passivation layer.

4. The device of claim 1, wherein the passivation layer includes a first passivation layer and a second passivation layer.

5. The device of claim 4, wherein the first passivation layer includes a hard passivation, and the second passivation layer includes a polymer passivation.

6. The device of claim 1, wherein the redistribution interconnect includes a seed layer.

7. The device of claim 1, wherein the redistribution interconnect comprises a thickness in a range of about 2-10 micrometers (μm).

8. The device of claim 1, further comprising a coating over the second surface of the redistribution interconnect.

9. The device of claim 8, wherein the coating is formed over a surface of the bump interconnect.

10. The device of claim 1, wherein the device is incorporated into a device selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, and a device in an automotive vehicle, and further including the device.

11. An apparatus comprising:
a semiconductor die;
a redistribution portion coupled to the semiconductor die, the redistribution portion comprising:
means for passivation; and
means for interconnect redistribution comprising a first surface and a second surface opposite to the first surface, the means for interconnect redistribution formed over the means passivation such that the first surface is over the means passivation and the second surface is free of contact with any means for passivation; and
a bump interconnect coupled to the second surface of the means for interconnect redistribution.

12. The apparatus of claim 11, wherein the bump interconnect comprises a surface that faces the means for interconnect redistribution, and wherein an entire surface of the bump interconnect that faces the means for interconnect redistribution touches the means for interconnect redistribution.

13. The apparatus of claim 11, wherein the bump interconnect comprises a surface that faces the means for interconnect redistribution, and wherein an entire surface of the bump interconnect that faces the means for interconnect redistribution is free of contact with the means for passivation.

14. The apparatus of claim 11, wherein the means for passivation includes a first passivation layer and a second passivation layer.

15. The apparatus of claim 14, wherein the first passivation layer includes a hard passivation, and the second passivation layer includes a polymer passivation.

16. The apparatus of claim 11, wherein the means for interconnect redistribution includes a seed layer.

17. The apparatus of claim 11, wherein the means for interconnect redistribution comprises a thickness in a range of about 2-10 micrometers (μm).

18. The apparatus of claim 11, further comprising a coating over the second surface of the means for interconnect redistribution.

19. The apparatus of claim 18, wherein the coating is formed over a surface of the bump interconnect.

20. The apparatus of claim 11, wherein the apparatus is incorporated into a device selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, and a device in an automotive vehicle, and further including the apparatus.

21. A method for fabricating a device, comprising:
providing a semiconductor die;
forming a redistribution portion over the semiconductor die, wherein forming the redistribution portion comprises:
forming a passivation layer; and
forming a redistribution interconnect comprising a first surface and a second surface opposite to the first surface, the redistribution interconnect formed over the passivation layer such that the first surface is over the passivation layer and the second surface is free of contact with any passivation layer; and
coupling a bump interconnect to the second surface of the redistribution interconnect.

22. The method of claim 21, wherein the bump interconnect comprises a surface that faces the redistribution interconnect, and wherein an entire surface of the bump interconnect that faces the redistribution interconnect touches the redistribution interconnect.

23. The method of claim 21, wherein the bump interconnect comprises a surface that faces the redistribution interconnect, and wherein an entire surface of the bump interconnect that faces the redistribution interconnect is free of contact with the passivation layer.

24. The method of claim 21, wherein forming the passivation layer includes forming a first passivation layer and forming a second passivation layer.

25. The method of claim 24, wherein the first passivation layer includes a hard passivation, and the second passivation layer includes a polymer passivation.

26. The method of claim 21, wherein forming the redistribution interconnect includes forming a seed layer.

27. The method of claim 21, wherein the redistribution interconnect comprises a thickness in a range of about 2-10 micrometers (μm).

28. The method of claim 21, further comprising forming a coating over the second surface of the redistribution interconnect.

29. The method of claim 28, wherein the coating is formed over a surface of the bump interconnect.

30. The method of claim 21, wherein the device is incorporated into a device selected from a group consisting of a music player, a video player, an entertainment unit, a navigation device, a communications device, a mobile device, a mobile phone, a smartphone, a personal digital assistant, a fixed location terminal, a tablet computer, a computer, a wearable device, a laptop computer, a server, and a device in an automotive vehicle, and further including the device.
